(19) United States
(12) Patent Application Publication
(10) Pub. No.: US 2012/0083133 A1
(43) Pub. Date: Apr. 5, 2012

(54) AMINE CURING SILICON-NITRIDE-HYDRIDE FILMS

(75) Inventors: Earl Osman Solis, San Jose, CA (US); Lili Ji, San Jose, CA (US); Yue Zhao, Mountain View, CA (US); Abhijit Basu Mallick, Palo Alto, CA (US); Nitin K. Ingle, San Jose, CA (US)

(73) Assignee: Applied Materials, Inc., Santa Clara, CA (US)

(21) Appl. No.: 13/227,589

(22) Filed: Sep. 8, 2011

Related U.S. Application Data
(60) Provisional application No. 61/389,917, filed on Oct. 5, 2010.

(51) Int. Cl. H01L 21/31

(52) U.S. Cl. 438/761; 257/E21.24

(57) ABSTRACT

Methods of forming dielectric layers are described. The methods may include forming a silicon-nitrogen-and-hydrogen-containing layer on a substrate. The methods include ozone curing the silicon-nitrogen-and-hydrogen-containing layer to turn the silicon-nitrogen-and-hydrogen-containing layer into a silicon-and-oxygen-containing layer. Following ozone curing, the layer is exposed to an amine-water combination at low temperature before an anneal. The presence of the amine cure allows the conversion to silicon-and-oxygen-containing layer to occur more rapidly and completely at a lower temperature during the anneal. The amine cure also enables the anneal to use a less oxidative environment to effect the conversion to the silicon-and-oxygen-containing layer.

### CROSS-REFERENCES TO RELATED APPLICATIONS

This application claims the benefit of U.S. Prov. Pat. App. No. 61/389,917 filed Oct. 5, 2010, and titled “AMINE CURING SILICON-NITRIDE-HYDRIDE FILMS,” which is entirely incorporated herein by reference for all purposes.

### BACKGROUND OF THE INVENTION

Semiconductor device geometries have dramatically decreased in size since their introduction several decades ago. Modern semiconductor fabrication equipment routinely produces devices with 45 nm, 32 nm, and 28 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., SOG deposition techniques). These flowable precursors can flow into and fill very small substrate gaps without forming voids or weak seams. However, once these highly flowable materials are deposited, they have to be hardened into a solid dielectric material.

In many instances, the hardening process includes a heat treatment to remove carbon and hydroxyl groups from the deposited material to leave behind a solid dielectric such as silicon oxide. Unfortunately, the departing carbon and hydroxyl species often leave behind pores in the hardened dielectric that reduce the quality of the final material. In addition, the hardening dielectric also tends to shrink in volume, which can leave cracks and spaces at the interface of the dielectric and the surrounding substrate. In some instances, the volume of the hardened dielectric can decrease by 40% or more.

Thus, there is a need for new deposition processes and materials to form dielectric materials on structured substrates without generating voids, seams, or both, in substrate gaps and trenches. There is also a need for materials and methods of hardening flowable dielectric materials with fewer pores and a lower decrease in volume. This and other needs are addressed in the present application.

### BRIEF SUMMARY OF THE INVENTION

Methods of forming dielectric layers are described. The methods may include forming a silicon-nitrogen-and-hydrogen-containing layer on a substrate. The methods include ozone curing the silicon-nitrogen-and-hydrogen-containing layer to turn the silicon-nitrogen-and-hydrogen-containing layer into a silicon-and-oxygen-containing layer. Following ozone curing, the layer is exposed to an amine-water combination at low temperature before an anneal. The presence of the amine cure allows the conversion to silicon-and-oxygen-containing layer to occur more rapidly and completely at a lower temperature during the anneal. The amine cure also enables the anneal to use a less oxidative environment to effect the conversion to the silicon-and-oxygen-containing layer.

Embodiments of the invention include methods of forming a silicon-and-oxygen-containing layer on a substrate. The methods comprising the sequential steps of: (1) depositing a silicon-nitrogen-and-hydrogen-containing layer on the substrate; (2) ozone curing the silicon-nitrogen-and-hydrogen-containing layer at an ozone curing temperature in an ozone-containing atmosphere to convert the silicon-nitrogen-and-hydrogen-containing layer into the silicon-and-oxygen-containing layer; and (3) amine curing the silicon-nitrogen-and-hydrogen-containing layer at an amine curing temperature in an atmosphere comprising an amine-containing precursor and water to form the silicon-and-oxygen-containing layer.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for making a silicon oxide film according to embodiments of the invention.

FIGS. 2 & 3 are FTIR spectra of dielectric films according to embodiments of the invention.

FIG. 4 shows a substrate processing system according to embodiments of the invention.

FIG. 5A shows a substrate processing chamber according to embodiments of the invention.

FIG. 5B shows a gas distribution showerhead according to embodiments of the invention.

### DETAILED DESCRIPTION OF THE INVENTION

Methods of forming dielectric layers are described. The methods may include forming a silicon-nitrogen-and-hydrogen-containing layer on a substrate. The methods include ozone curing the silicon-nitrogen-and-hydrogen-containing layer to turn the silicon-nitrogen-and-hydrogen-containing layer into a silicon-and-oxygen-containing layer. Following ozone curing, the layer is exposed to an amine-water combination at low temperature before an anneal. The presence of the amine cure allows the conversion to silicon-and-oxygen-containing layer to occur more rapidly and completely at a lower temperature during the anneal. The amine cure also enables the anneal to use a less oxidative environment to effect the conversion to the silicon-and-oxygen-containing layer.

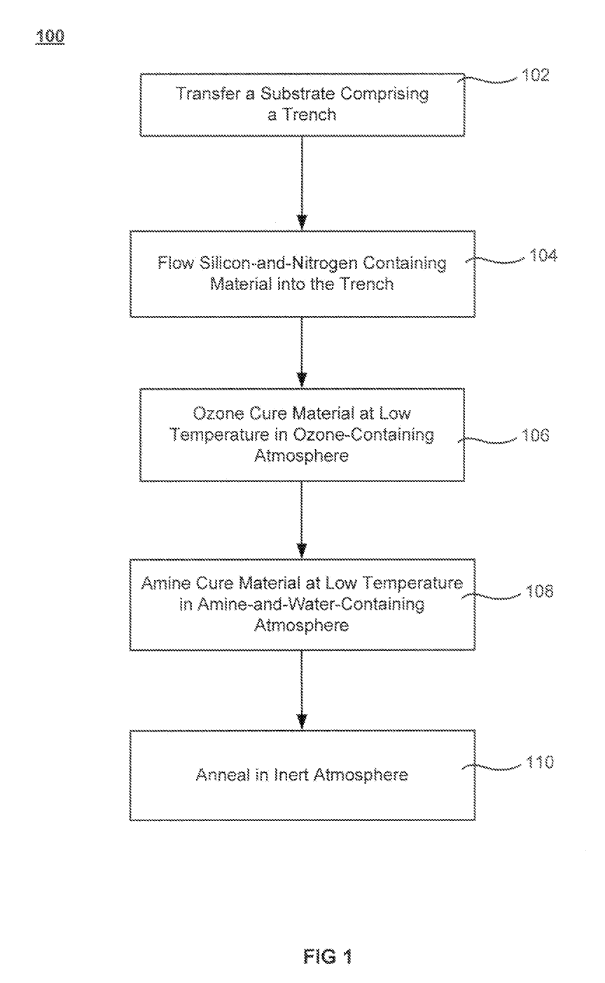

In order to better understand and appreciate the invention, reference is now made to FIG. 1 which is a flowchart showing selected steps in methods 100 of making silicon oxide films according to embodiments of the invention. Though these processes are useful for a variety of surface topologies, the exemplary method 100 includes transferring a substrate comprising a narrow gap into a substrate processing region (operation 102). The substrate may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths that range from about 90 nm to about 22 nm or less (e.g., less than 90 nm, 65 nm, 50 nm, 45 nm, 32 nm, 22 nm, 16 nm, etc.).

Exemplary method 100 includes forming a silicon-nitrogen-and-hydrogen-containing layer on the substrate and in the narrow gap. Spin-on dielectric (SOD) films fall under this category as well as some chemical vapor deposition techniques. Silicon-nitrogen-and-hydrogen-containing layers may be deposited to flow in and fill the narrow gap and may then be converted to silicon oxide. Silicon-nitrogen-and-hydrogen-containing layers deposited by chemical vapor deposition may also be deposited conformally (e.g. as a liner) before a subsequent film is deposited. Each of these regimes, as well as intervening regimes, are included in silicon-nitrogen-and-hydrogen-containing layers referenced herein.

Following the deposition of the silicon-nitrogen-and-hydrogen-containing layer, the deposition substrate may be ozone cured in an ozone-containing atmosphere 106. The curing operation reduces the concentration of nitrogen while increasing the concentration of oxygen in the film, including in the trench. The deposition substrate may remain in the substrate processing region for curing, or the substrate may be transferred to a different chamber where the ozone-containing atmosphere is introduced. The ozone curing temperature of the substrate may be less than or about 400° C., less than or about 300° C., less than or about 250° C., less than or about 200° C. or less than or about 150° C. in different embodiments. The temperature of the substrate may be greater than or about room temperature (25° C.), greater than or about 50° C., greater than or about 100° C., greater than or about 150° C. or greater than or about 200° C. in disclosed embodiments. Any of the upper bounds may be combined with any of the lower bounds to form additional ranges for the substrate temperature according to additional disclosed embodiments. No plasma is present in the substrate processing region, in embodiments, to avoid generating atomic oxygen which may close the near surface network and thwart subsurface oxidation. The duration of the ozone cure may be greater than about 5 seconds or greater than about 10 seconds in embodiments. The duration of the ozone cure may be less than about 60 seconds or less than or about 45 seconds in embodiments. Again, upper bounds may be combined with lower bounds to form additional ranges for the duration of the ozone cure according to additional disclosed embodiments.

The flow rate of the ozone (just the ozone contribution) into the substrate processing region during the cure step may be greater than or about 500 sccm, greater than or about 1 slm, greater than or about 2 slm or greater than or about 2 slm, in disclosed embodiments. The partial pressure of ozone during the cure step may be greater than or about 20 Torr, greater than or about 30 Torr, greater than or about 50 Ton or greater than or about 100 Torr, in disclosed embodiments. In some cases, exposure to an increasing temperature from below or about 250° C. to a temperature above 400° C. (e.g. 550° C.) has furthered the conversion from the silicon-nitrogen-and-hydrogen-containing film to the silicon oxide film. Adding moisture (steam/H₂O) to the ozone-containing atmosphere has also increased the conversion to the silicon oxide film, when provided at the increased temperature (above 400° C.).

Following ozone curing of the silicon-and-nitrogen-containing layer, the deposition substrate may be amine cured in an amine-and-water-containing atmosphere 108. The amine-and-water-containing atmosphere also contains water vapor which may be referred to herein as steam. Again, the deposition substrate may remain in the same substrate processing region used for curing when the amine-and-water-containing atmosphere is introduced, or the substrate may be transferred to a different chamber for amine cure step 108.

Generally speaking, the amine-and-water-containing atmosphere may include an amine-containing precursor and water. The amine-containing precursor may or may not contain ammonia but contains a nitrogen atom having a lone pair of electrons. The lone pair of electrons does not participate in a chemical bond during some of the journey towards the substrate surface. The water and amine (e.g. ammonia) may interact prior to arrival at the surface and create combined precursors. The amine curing temperature of the substrate may be less than or about 300° C., less than or about 200° C., less than or about 150° C., less than or about 100° C. or less than or about 75° C. in different embodiments. The temperature of the substrate may be greater than or about room temperature (25° C.), greater than or about 50° C., greater than or about 75° C., greater than or about 100° C. or greater than or about 150° C. in different embodiments. Any of the upper bounds may be combined with any of the lower bounds to form additional ranges for the substrate temperature according to additional disclosed embodiments. In disclosed embodiments, the amine curing temperature is less than or approximately equal to the ozone curing temperature. The duration of the amine cure may be greater than about 5 seconds or greater than about 10 seconds in embodiments. The duration of the amine cure may be less than about 60 seconds or less than or about 45 seconds in embodiments. Again, upper bounds may be combined with lower bounds to form additional ranges for the duration of the amine cure according to additional disclosed embodiments.

No plasma is present in the substrate processing region, in embodiments, to avoid generating hyper-reactive oxygen and nitrogen which may modify the near surface network and thwart subsurface penetration of the favorable chemical reaction. The flow rate of the amine precursor into the substrate processing region during amine cure step 108 may be greater than or about 5 slm, greater than or about 10 slm, greater than or about 20 slm or greater than or about 40 slm, in disclosed embodiments. The partial pressure of the amine precursor during the amine cure step may be greater than or about 50 Torr, greater than or about 100 Torr, greater than or about 150 Ton or greater than or about 200 Torr, in disclosed embodiments. The flow rate of the steam into the substrate processing region during the amine cure step may be greater than or about 1 slm, greater than or about 2 slm, greater than or about 5 slm or greater than or about 10 slm, in disclosed embodiments. The partial pressure of the steam during the amine cure step may be greater than or about 10 Torr, greater than or about 20 Ton, greater than or about 40 Ton or greater than or about 50 Ton, in disclosed embodiments. The flow rate ratio (e.g. in sccms) of the amine precursor to the steam may be greater than about 1:1, 2:1 or 3:1 in embodiments of the invention. A ratio greater than x:y is defined as having a ratio greater than x/y.

Following amine curing, the converted silicon-and-oxygen-containing layer may be dry annealed in an dry environment at high temperature to complete the formation of a silicon oxide film 110. The dry atmosphere may be essentially a vacuum, or it may include a noble gas or another inert gas: any chemical which does not significantly become incorporated in the converting film. The dry anneal temperature of the substrate may be less than or about 1100° C., less than or about 1000° C., less than or about 900° C. or less than or about 800° C. in different embodiments. The temperature of the substrate may be greater than or about 500° C., greater than or about 600° C., greater than or about 700° C. or greater than or about 800° C. in different embodiments. The dry anneal may be in-situ or in another processing region/system and may occur as a batch or single wafer process.

The oxygen-containing atmospheres of the curing operations each may provide oxygen to convert the silicon-nitrogen-and-hydrogen-containing film into the silicon-and-oxygen-containing film or the silicon oxide film. Carbon may or may not be present in the silicon-nitrogen-and-hydrogen-containing film in embodiments of the invention. If absent, the lack of carbon in the silicon-nitrogen-and-hydrogen-containing film results in significantly fewer pores formed in the final silicon oxide film. It also results in less volume reduction (i.e., shrinkage) of the film during the conversion to the silicon oxide. For example, where a silicon-nitrogen-carbon layer formed from carbon-containing silicon precursors may shrink by 40 vol. % or more when converted to silicon oxide, the substantially carbon-free silicon-and-nitrogen-containing films may shrink by about 15 vol. % or less. As a result of the flowability of the silicon-nitrogen-and-hydrogen-containing film and the lack of shrinkage, the silicon-and-oxygen-containing film produced according to methods 100 may fill the narrow trench so it is free of voids.

An exemplary operation of depositing the silicon-nitrogen-and-hydrogen-containing layer may involve a chemical vapor deposition process which begins by providing a carbon-free silicon precursor to a substrate processing region. The carbon-free silicon-containing precursor may be, for example, a silicon-and-nitrogen-containing precursor, a silicon-and-hydrogen precursor, or a silicon-nitrogen-and-hydrogen-containing precursor, among other classes of silicon precursors. The silicon-precursor may be oxygen-free in addition to carbon-free. The lack of oxygen results in a lower concentration of silanol (Si—OH) groups in the silicon-and-nitrogen-containing layer formed from the precursors. Excess silanol moieties in the deposited film can cause increased porosity and shrinkage during post deposition steps that remove the hydroxyl (—OH) moieties from the deposited layer.

Specific examples of carbon-free silicon precursors may include silyl-amines such as H₂N(SiH₃), HN(SiH₃)₂, and N(SiH₃)₃, among other silyl-amines. The flow rates of a silyl-amine may be greater than or about 200 sccm, greater than or about 300 sccm or greater than or about 500 sccm in different embodiments. All flow rates given herein refer to a dual chamber substrate processing system. Single wafer systems would require half these flow rates and other wafer sizes would require flow rates scaled by the processed area. These silyl-amines may be mixed with additional gases that may act as carrier gases, reactive gases, or both. Examplary additional gases include H₂, N₂, NH₃, He, and Ar, among other gases. Examples of carbon-free silicon precursors may also include silane (SiH₄) either alone or mixed with other silicon (e.g., N(SiH₃)₃), hydrogen (e.g., H₂), and/or nitrogen (e.g., N₂, NH₃) containing gases. Carbon-free silicon precursors may also include disilane, trisilane, even higher-order silanes, and chlorinated silanes, alone or in combination with one another or the previously mentioned carbon-free silicon precursors.

A radical-nitrogen precursor may also be provided to the substrate processing region. The radical-nitrogen precursor is a nitrogen-radical-containing precursor that was generated outside the substrate processing region from a more stable nitrogen precursor. For example, a stable nitrogen precursor compound containing NH₃, hydrazine (N₂H₄) and/or N₂ may be activated in a chamber plasma region or a remote plasma system (RPS) outside the processing chamber to form the radical-nitrogen precursor, which is then transported into the substrate processing region. The stable nitrogen precursor may also be a mixture comprising NH₃ & N₂, NH₃ & H₂, NH₃ & N₂ & H₂ and N₂ & H₂, in different embodiments. Hydrazine may also be used in place of or in combination with NH₃ in the mixtures with N₂ and H₂. The flow rate of the stable nitrogen precursor may be greater than or about 300 sccm, greater than or about 500 sccm or greater than or about 700 sccm in different embodiments. The radical-nitrogen precursor produced in the chamber plasma region may be one or more of *N, *NH, *NH₂, etc., and may also be accompanied by ionized species formed in the plasma. Sources of oxygen may also be combined with the more stable nitrogen precursor in the remote plasma which will act to pre-load the film with oxygen while decreasing flowability. Sources of oxygen may include one or more of O₂, H₂O, O₃, H₂O₂, N₂O, NO or NO₂. Generally speaking, a radical precursor may be used which does not contain nitrogen and the nitrogen for the silicon-nitrogen-and-hydrogen-containing layer is then provided by nitrogen from the carbon-free silicon-containing precursor.

In embodiments employing a chamber plasma region, the radical-nitrogen precursor is generated in a section of the substrate processing region partitioned from a deposition region where the precursors mix and react to deposit the silicon-and-nitrogen-containing layer on a deposition substrate (e.g., a semiconductor wafer). The radical-nitrogen precursor may also be accompanied by a carrier gas such as hydrogen (H₂), nitrogen (N₂), helium, etc. The substrate processing region may be described herein as “plasma-free” during the growth of the silicon-nitrogen-and-hydrogen-containing layer and during the low temperature ozone cure. “Plasma-free” does not necessarily mean the region is devoid of plasma. The borders of the plasma in the chamber plasma region are hard to define and may encroach upon the substrate processing region through the apertures in the showerhead. In the case of an inductively-coupled plasma, e.g., a small amount of ionization may be initiated within the substrate processing region directly. Furthermore, a low intensity plasma may be created in the substrate processing region without eliminating the flowable nature of the forming film. All causes for a plasma having much lower ion density than the chamber plasma region during the creation of the radical nitrogen precursor do not deviate from the scope of “plasma-free” as used herein. The substrate processing region may also be plasma-free, using the same definition, during the amine cures described herein.

In the substrate processing region, the carbon-free silicon precursor and the radical-nitrogen precursor mix and react to deposit a silicon-nitrogen-and-hydrogen-containing film on the deposition substrate. The deposited silicon-nitrogen-and-hydrogen-containing film may deposit conformally with some recipe combinations in embodiments. In other embodiments, the deposited silicon-nitrogen-and-hydrogen-containing film has flowable characteristics unlike conventional silicon nitride (Si₃N₄) film deposition techniques. The flowable nature of the formation allows the film to flow into narrow gaps trenches and other structures on the deposition surface of the substrate.

The flowability may be due to a variety of properties which result from mixing a radical-nitrogen precursors with carbon-free silicon precursor. These properties may include a significant hydrogen component in the deposited film and/or the presence of short chained polysilazane polymers. These short chains grow and network to form more dense dielectric material during and after the formation of the film. For example the deposited film may have a silazane-type, Si—NH-Si backbone (i.e., a carbon-free Si—N—H film). When both the silicon precursor and the radical-nitrogen precursor are carbon-free, the deposited silicon-nitrogen-and-hydrogen-containing film is also substantially carbon-free. Of course, “carbon-free” does not necessarily mean the film lacks even trace amounts of carbon. Carbon contaminants may be present in the precursor materials that find their way into the deposited silicon-and-nitrogen-containing precursor. The amount of these carbon impurities however are much less than would be found in a silicon precursor having a carbon moiety (e.g., TEOS, TMDSO, etc.).

As described above, the deposited silicon-nitrogen-and-hydrogen-containing layer may be produced by combining a radical-nitrogen precursor with a variety of carbon-free silicon-containing precursors. The carbon-free silicon-containing precursor may be essentially nitrogen-free, in embodiments. In some embodiments, both the carbon-free silicon-containing precursor and the radical-nitrogen precursor contain nitrogen. On the other hand, the radical precursor may be essentially nitrogen-free, in embodiments, and the nitrogen for the silicon-nitrogen-and-hydrogen-containing layer may be supplied by the carbon-free silicon-containing precursor. So most generally speaking, the radical precursor will be referred to herein as a “radical-nitrogen-and/or-hydrogen precursor,” which means that the precursor contains nitrogen and/or hydrogen. Analogously, the precursor flowed into the plasma region to form the radical-nitrogen-and/or-hydrogen precursor will be referred to as a nitrogen-and/or-hydrogen-containing precursor. These generalizations may be applied to each of the embodiments disclosed herein. In embodiments, the nitrogen-and/or-hydrogen-containing precursor comprises hydrogen (H₂) while the radical-nitrogen-and/or-hydrogen precursor comprises .H, etc.

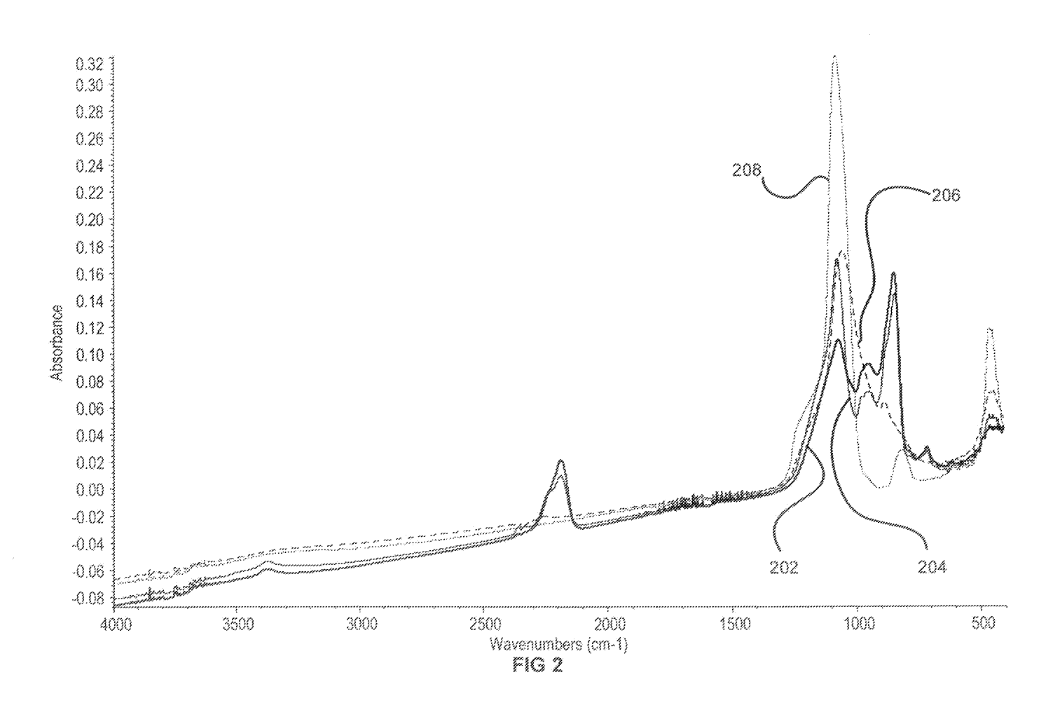

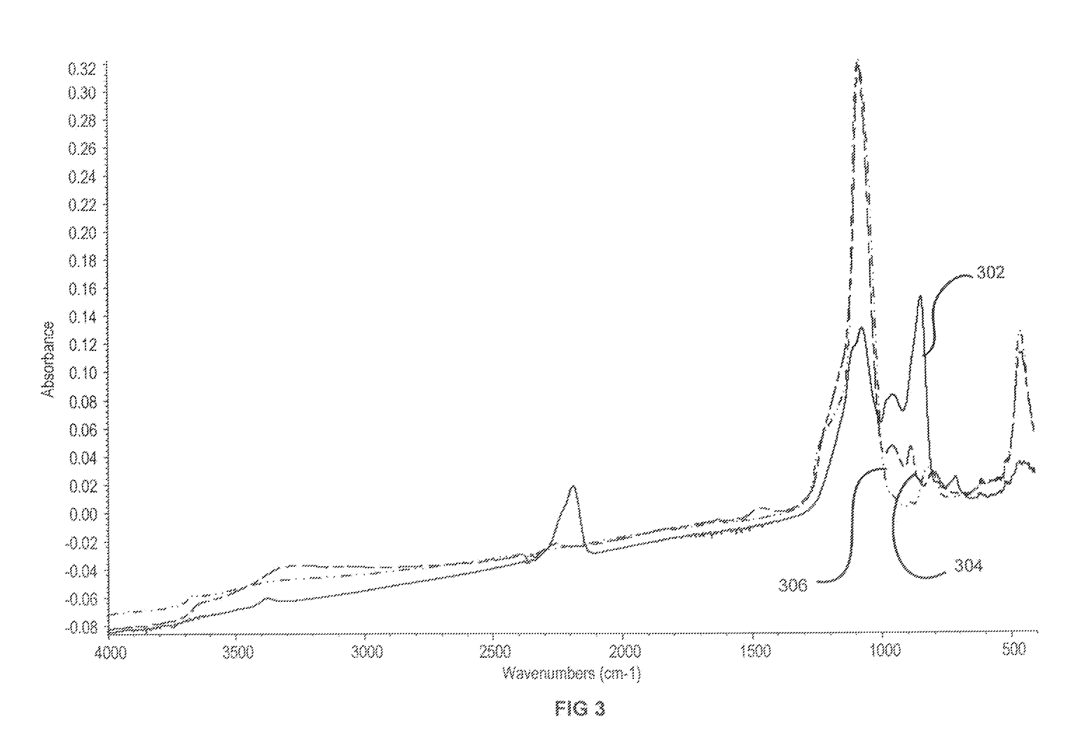

Reference is now made to FIGS. 2-3, which are FTIR spectra of dielectric films according to embodiments of the invention. The amine curing treatment described herein follows the ozone curing operation. FIG. 2 shows the FTIR spectra at various points during processing without using an amine cure. A spectrum 202 is shown following a moderate ozone cure which lasted about forty seconds. An FTIR spectrum 204 is also shown after sequential application of a moderate ozone cure and then a low temperature water cure. In each of the two FTIR spectra, 202 and 204, there is a pronounced peak near 900 cm⁻¹ indicating the presence of Si—N bonds within the 3 kA silicon-and-oxygen-containing layer. Another FTIR spectrum 206 is shown following a high temperature dry anneal and the spectrum 206 indicates a reduced (but still significant) concentration of Si—N. Another substrate was processed under the same condition as spectrum 206 with the sole exception of using an extended ozone cure (100 seconds instead of 40 seconds) and the result is shown as FTIR spectrum 208. FTIR spectrum 208 indicates very little Si—N left in the silicon-and-oxygen-containing film and represents a goal upon introducing the amine cure in FIG. 3.

Introducing the amine curing operation enables the Si—N FTIR signature to be essentially removed without using an extended ozone treatment. FIG. 3 shows the FTIR spectra from a silicon-and-oxygen-containing layer formed using a moderate ozone cure (not an extended ozone cure) followed by an amine cure. Spectra are shown following the amine cure 302, following a subsequent low temperature water cure 304 and following the dry anneal 306. The inclusion of the amine cure does not appear to change the FTIR spectra when spectra are acquired following the amine cure (compare 202 (no amine cure) with 302 (w/amine cure)). However, the presence of the amine cure decreases the Si—N peak at 900 cm⁻¹ following the low temperature water cure (compare 204 with 304). No oxygen treatments are required after the low temperature water cure, in disclosed embodiments, and the wafer throughput can be significantly increased. A dry anneal essentially completes the conversion to the silicon-and-oxygen-containing layer in embodiments of the invention.

Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

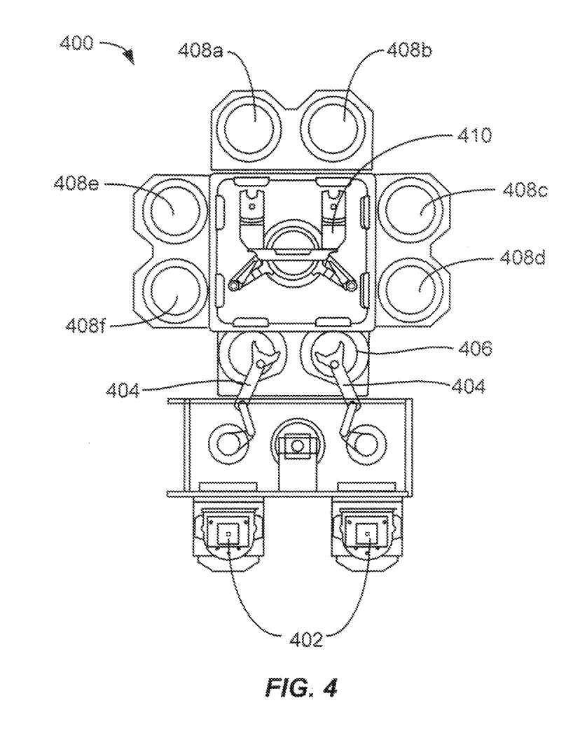

Embodiments of the deposition systems may be incorporated into larger fabrication systems for producing integrated circuit chips. FIG. 4 shows one such system 400 of deposition, baking and curing chambers according to disclosed embodiments. In the figure, a pair of FOUPs (front opening unified pods) 402 supply substrates (e.g., 300 mm diameter wafers) that are received by robotic arms 404 and placed into a low pressure holding area 406 before being placed into one of the wafer processing chambers 408a-f. A second robotic arm 410 may be used to transport the substrate wafers from the holding area 406 to the processing chambers 408a-f and back.

The processing chambers 408a-f may include one or more system components for depositing, annealing, curing and/or etching a flowable dielectric film on the substrate wafer. In one configuration, two pairs of the processing chamber (e.g., 408c-d and 408e-f) may be used to deposit the flowable dielectric material on the substrate, and the third pair of processing chambers (e.g., 408a-b) may be used to anneal the deposited dielectic. In another configuration, the same two pairs of processing chambers (e.g., 408c-d and 408e-f) may be configured to both deposit and anneal a flowable dielectric film on the substrate, while the third pair of chambers (e.g., 408a-b) may be used for UV or E-beam curing of the deposited film. In still another configuration, all three pairs of chambers (e.g., 408a-f) may be configured to deposit and cure a flowable dielectric film on the substrate. In yet another configuration, two pairs of processing chambers (e.g., 408c-d and 408e-f) may be used for both deposition and UV or E-beam curing of the flowable dielectric, while a third pair of processing chambers (e.g. 408a-b) may be used for annealing the dielectric film. Any one or more of the processes described may be carried out on chamber(s) separated from the fabrication system shown in different embodiments.

In addition, one or more of the process chambers 408a-f may be configured as a wet treatment chamber. These process chambers include heating the flowable dielectric film in an atmosphere that includes moisture. Thus, embodiments of system 400 may include wet treatment chambers 408a-b and anneal processing chambers 408c-d to perform both wet and dry anneals on the deposited dielectric film.

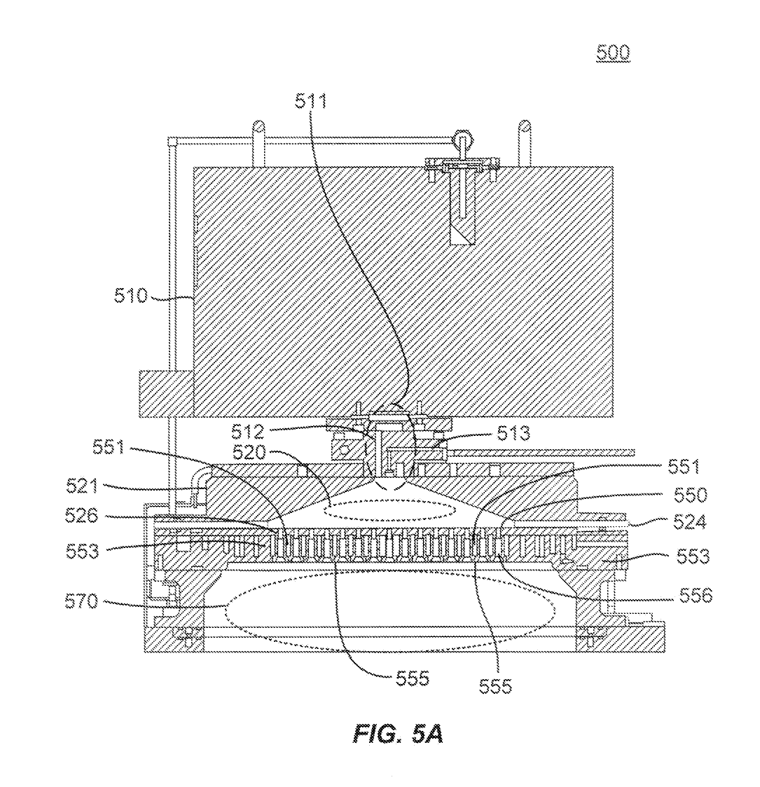

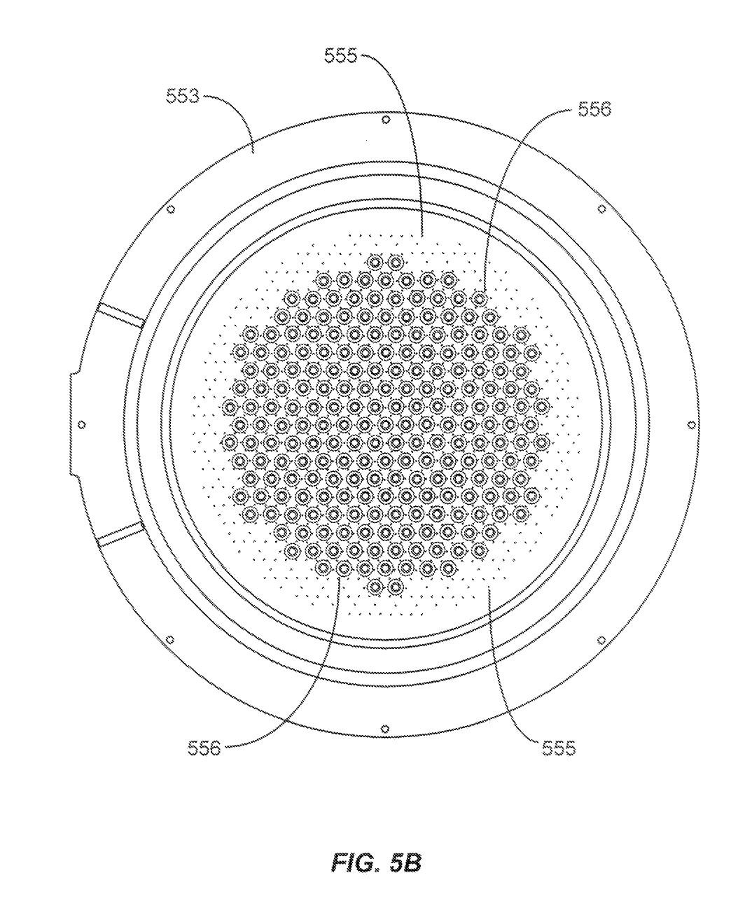

FIG. 5A is a substrate processing chamber 500 according to disclosed embodiments. A remote plasma system (RPS) 510 may process a gas which then travels through a gas inlet assembly 511. Two distinct gas supply channels are visible within the gas inlet assembly 511. A first channel 512 carries a gas that passes through the remote plasma system RPS 510, while a second channel 513 bypasses the RPS 510. The first channel 502 may be used for the process gas and the second channel 513 may be used for a treatment gas in disclosed embodiments. The lid (or conductive top portion) 521 and a perforated partition (also referred to as a showerhead) 553 are shown with an insulating ring 524 in between, which allows an AC potential to be applied to the lid 521 relative to perforated partition 553. The process gas travels through first channel 512 into chamber plasma region 520 and may be excited by a plasma in chamber plasma region 520 alone or in combination with RPS 510. The combination of chamber plasma region 520 and/or RPS 510 may be referred to as a remote plasma system herein. The perforated partition (showerhead) 553 separates chamber plasma region 520 from a substrate processing region 570 beneath showerhead 553. Showerhead 553 allows a plasma present in chamber plasma region 520 to avoid directly exciting gases in substrate processing region 570, while still allowing excited species to travel from chamber plasma region 520 into substrate processing region 570.

Showerhead 553 is positioned between chamber plasma region 520 and substrate processing region 570 and allows plasma effluents (excited derivatives of precursors or other gases) created within chamber plasma region 520 to pass through a plurality of through-holes 556 that traverse the thickness of the plate. The showerhead 553 also has one or more hollow volumes 551 which can be filled with a precursor in the form of a vapor or gas (such as a silicon-containing precursor) and pass through small holes 555 into substrate processing region 570 but not directly into chamber plasma region 520. Showerhead 553 is thicker than the length of the smallest diameter 550 of the through-holes 556 in this disclosed embodiment. In order to maintain a significant concentration of excited species penetrating from chamber plasma region 520 to substrate processing region 570, the length 526 of the smallest diameter 550 of the through-holes may be restricted by forming larger diameter portions of through-holes 556 part way through the showerhead 553. The length of the smallest diameter 550 of the through-holes 556 may be the same order of magnitude as the smallest diameter of the through-holes 556 or less in disclosed embodiments.

In the embodiment shown, showerhead 553 may distribute (via through-holes 556) process gases which contain oxygen, hydrogen and/or nitrogen and/or plasma effluents of such process gases upon excitation by a plasma in chamber plasma region 520. In embodiments, the process gas introduced into the RPS 510 and/or chamber plasma region 520 through first channel 512 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 513 may also deliver a process gas and/or a carrier gas, and/or a film-curing gas used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 556 may be between about 60 and about 2000. Through-holes 556 may have a variety of shapes but are most easily made round. The smallest diameter 550 of through-holes 556 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 555 used to introduce a gas into substrate processing region 570 may be between about 100 and about 5000 or between about 500 and about 2000 in different embodiments. The diameter of the small holes 555 may be between about 0.1 mm and about 2 mm.

FIG. 5B is a bottom view of a showerhead 553 for use with a processing chamber according to disclosed embodiments. Showerhead 553 corresponds with the showerhead shown in FIG. 5A. Through-holes 556 are depicted with a larger inner-diameter (ID) on the bottom of showerhead 553 and a smaller ID at the top. Small holes 555 are distributed substantially evenly over the surface of the showerhead, even amongst the through-holes 556 which helps to provide more even mixing than other embodiments described herein.

An exemplary film is created on a substrate supported by a pedestal (not shown) within substrate processing region 570 when plasma effluents arriving through through-holes 556 in showerhead 553 combine with a silicon-containing precursor arriving through the small holes 555 originating from hollow volumes 551. Though substrate processing region 570 may be equipped to support a plasma for other processes such as curing, no plasma is present during the growth of the exemplary film.

A plasma may be ignited either in chamber plasma region 520 above showerhead 553 or substrate processing region 570 below showerhead 553. A plasma is present in chamber plasma region 520 to produce the radical nitrogen precursor from an inflow of a nitrogen-and-hydrogen-containing gas. An AC voltage typically in the radio frequency (RF) range is applied between the conductive top lid 521 of the processing chamber and showerhead 553 to ignite a plasma in chamber plasma region 520 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 570 is turned on to either cure a film or clean the interior surfaces bordering substrate processing region 570. A plasma in substrate processing region 570 is ignited by applying an AC voltage between showerhead 553 and the pedestal or bottom of the chamber. A cleaning gas may be introduced into substrate processing region 570 while the plasma is present. No plasma is used during amine curing, in embodiments of the invention.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. In some embodiments of the invention, silicon oxide consists essentially of silicon and oxygen. A gas in an “excited state” describes a gas wherein at least some of the gas molecules are in vibrationally-excited, dissociated and/or ionized states. A gas (or precursor) may be a combination of two or more gases (precursors). The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. The term “precursor” is used to refer to any process gas (or vaporized liquid droplet) which takes part in a reaction to either remove or deposit material from a surface.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a silicon-and-oxygen-containing layer on a substrate, the method comprising the sequential steps of:
depositing a silicon-nitrogen-and-hydrogen-containing layer on the substrate;
ozone curing the silicon-nitrogen-and-hydrogen-containing layer at an ozone curing temperature in an ozone-containing atmosphere to convert the silicon-nitrogen-and-hydrogen-containing layer into the silicon-and-oxygen-containing layer; and
amine curing the silicon-nitrogen-and-hydrogen-containing layer at an amine curing temperature in an atmosphere comprising an amine-containing precursor and water to form the silicon-and-oxygen-containing layer.

2. The method of claim 1 wherein the silicon-nitrogen-and-hydrogen-containing layer is a carbon-free silicon-nitrogen-and-hydrogen-containing layer.

3. The method of claim 1 wherein the silicon-nitrogen-and-hydrogen-containing layer is formed by:
flowing a nitrogen-and/or-hydrogen-containing precursor into a plasma region to produce a radical-nitrogen-and/or-hydrogen precursor;
combining a silicon-containing precursor with the radical-nitrogen-and/or-hydrogen precursor in a plasma-free substrate processing region; and
depositing the silicon-nitrogen-and-hydrogen-containing layer on the substrate.

4. The method of claim 3 wherein the silicon-containing precursor is a carbon-free silicon-containing precursor.

5. The method of claim 3 wherein the nitrogen-and/or-hydrogen-containing precursor comprises at least one of N₂H₂, NH₃, N₂ and H₂.

6. The method of claim 3 wherein the silicon-containing precursor comprises a silicon-and-nitrogen-containing precursor.

7. The method of claim 3 wherein the silicon-containing precursor comprises N(SiH₃)₃.

8. The method of claim 1 wherein the ozone curing temperature is less than 250° C.

9. The method of claim 1 wherein the amine curing temperature is less than 150° C.

10. The method of claim 1 wherein the amine curing step occurs in a plasma-free substrate processing region.

11. The method of claim 1 wherein the ozone-containing atmosphere further comprises steam while the substrate is at the ozone curing temperature.

12. The method of claim 1 wherein the amine curing temperature is less than or about the ozone curing temperature.

13. The method of claim 1 wherein a duration of the ozone curing step exceeds about 20 seconds.

14. The method of claim 1 wherein a duration of the amine curing step exceeds about 20 seconds.

15. The method of claim 1 wherein the silicon-nitrogen-and-hydrogen-containing layer comprises Si—N and Si—H bonds.

16. The method of claim 1 further comprising raising a temperature of the substrate to a dry anneal temperature above or about 500° C. after the amine curing step.

17. The method of claim 1 wherein the substrate is patterned and has a trench having a width of about 32 nm or less.

18. The method of claim 1 wherein the amine-containing precursor comprises ammonia.
